(19) United States
(12) Patent Application Publication
(10) Pub. No.: US 2024/0347343 A1
(43) Pub. Date: Oct. 17, 2024

(54) NITRIDE SEMICONDUCTOR DEVICE, NITRIDE SEMICONDUCTOR SUBSTRATE, AND METHOD OF MANUFACTURING NITRIDE SEMICONDUCTOR DEVICE

(71) Applicant: NATIONAL UNIVERSITY CORPORATION TOKAI NATIONAL HIGHER EDUCATION AND RESEARCH SYSTEM, Nagoya-shi (JP)

(72) Inventors: Manato DEKI, Nagoya-shi (JP); Shun LU, Nagoya-shi (JP); Hiroshi AMANO, Nagoya-shi (JP); Yoshio HONDA, Nagoya-shi (JP); Atsushi TANAKA, Nagoya-shi (JP); Yuta ITO, Nagoya-shi (JP)

(21) Appl. No.: 18/292,031

(22) PCT Filed: Feb. 15, 2022
(86) PCT No.: PCT/JP2022/005973

§ 371 Date: Jan. 25, 2024

(30) Foreign Application Priority Data
Jul. 26, 2021 (JP) 2021-121826
Oct. 26, 2021 (JP) 2021-174661

(51) Int. Cl. H01L 21/285; H01L 21/265; H01L 21/266; H01L 29/20; H01L 29/45; H01L 29/66; H01L 29/778

(52) U.S. Cl. CPC H01L 21/28575; H01L 21/2654; H01L 21/266; H01L 29/2003; H01L 29/452; H01L 29/66462; H01L 29/7786

(57) ABSTRACT

A technology is provided to form p-type regions and to effectively reduce a contact resistance between the p-type region and an electrode. One embodiment of a nitride semiconductor device manufacturing method may include a magnesium layer formation step of forming a magnesium layer that comprises magnesium as a major component on a surface of a nitride semiconductor substrate. The method may include an annealing step of annealing the nitride semiconductor substrate on which the magnesium layer is formed.

This application claims priority to Japanese Patent Application No. 2021-121826 filed on Jul. 26, 2021 and Japanese Patent Application No. 2021-174661 filed on Oct. 26, 2021. The entire contents of those applications are hereby incorporated by reference in to the description herein. The art disclosed herein relates to a nitride semiconductor device, a nitride semiconductor substrate, and a method of manufacturing a nitride semiconductor device.

### BACKGROUND ART

A technique is known that forms a p-type region by ion-implanting magnesium (Mg), which is an acceptor impurity, at an arbitrary position in a nitride semiconductor substrate. Further, there is also a known technique that forms an electrode on the p-type region. Furthermore, JP-2021-28932 A and US 2019/393038 A1 describe related techniques.

### SUMMARY OF INVENTION

### Technical Problem

This specification provides an art configured capable of forming a p-type region and effectively reducing a contact resistance between the p-type region and an electrode.

### Solution to Technical Problem

The description herein discloses a method of manufacturing a nitride semiconductor device. The method may comprise a magnesium layer formation step of forming a magnesium layer that comprises magnesium as a major component on a surface of a nitride semiconductor substrate. The method may comprise an annealing step of annealing the nitride semiconductor substrate on which the magnesium layer is formed.

Inventors have created a technique for forming annealing a magnesium layer on a nitride semiconductor substrate. Due to this, a p-type region can be formed and a contact resistance between the p-type region and an electrode can effectively be reduced.

In the magnesium layer formation step, the magnesium layer may be formed on at least a part of a surface of a p-type region of the nitride semiconductor substrate having the p-type region exposed on at least a part of its surface. In the annealing step, the nitride semiconductor substrate on which the magnesium layer is formed may be annealed in an atmosphere containing nitrogen to transform the magnesium layer into an intermediate layer containing magnesium and nitrogen. The method may further comprise an electrode formation step of forming an electrode layer on at least a part of an upper surface of the intermediate layer.

The method may further comprise a step of decreasing a film thickness of the intermediate layer that is performed after the annealing step. The electrode formation step may form the electrode layer on the upper surface of the intermediate layer after having decreased the film thickness.

In the magnesium layer formation step, the magnesium layer may be selectively formed in a specific region that is at least a part of the surface of the p-type region.

The magnesium layer formation step may comprise a step of forming, a mask layer including an opening corresponding to the specific region, on a surface of the nitride semiconductor substrate. The magnesium layer formation step may comprise a step of depositing the magnesium layer via the mask layer.

An n-type region may be exposed on a part of a surface of the nitride semiconductor substrate. In the magnesium layer formation step, the magnesium layer may be formed on at least a part of the surface of the p-type region but may not be formed on a surface of the n-type region. In the electrode layer formation step, the electrode layer may be formed to traverse across the intermediate layer that is formed in the p-type region and the n-type region.

The method may further comprise a defect formation step of forming crystal defects in the nitride semiconductor substrate from a surface of nitride semiconductor substrate. The magnesium layer may be a solid layer.

A diffusion rate can be increased by thermal diffusion of Mg into regions where crystal defects are formed. Solid phase diffusion can also diffuse Mg to a sufficient depth. Since Mg ion implantation need not be used, the generation of nitrogen vacancies can be suppressed. As a result, it is possible to form p-type regions.

The method may further comprise a protective layer formation step of forming a protective layer on a surface of the magnesium layer. In the annealing step, the nitride semiconductor substrate on which the protective layer is formed may be heated.

The method may further comprise a pre-annealing step of heating the nitride semiconductor substrate at a lower temperature than in the annealing step. The pre-annealing step may be performed after the magnesium layer formation step and before the protective layer formation step.

The method may further comprise a step of removing an altered layer formed on the surface of the magnesium layer by the pre-annealing step. The protective layer may be formed on the surface of the magnesium layer from which the altered layer has been removed.

The method may further comprise a defect formation step of forming crystal defects in the nitride semiconductor substrate from a surface of nitride semiconductor substrate. The magnesium layer may be a melt containing magnesium.

The melt may contain Zn. A temperature of the melt may be 450° C. or higher.

The defect formation step may comprise a step of implanting nitrogen ions from a surface of the nitride semiconductor substrate.

The description herein discloses a nitride semiconductor device. The nitride semiconductor device may comprise a nitride semiconductor substrate having a p-type region exposed on at least a part of its surface. The nitride semiconductor device may comprise an intermediate layer arranged at least in a part of an upper surface of the p-type region and containing magnesium and nitrogen. The nitride semiconductor device may comprise an electrode layer arranged on at least a part of an upper surface of the intermediate layer.

The inventors have created a configuration in which the intermediate layer containing magnesium and nitrogen is arranged between the p-type region of the nitride semiconductor substrate and the electrode layer. This enables to significantly reduce the contact resistance between the p-type region and the electrode layer as compared to a case in which no intermediate layer is arranged.

The intermediate layer may have an amorphous structure.

The intermediate layer may contain gallium. A concentration of the gallium in the intermediate layer may decrease as a distance from an interface between the p-type region and the intermediate layer increases.

An impurity concentration of the p-type region may be in a range of 1×10¹⁶ to 1×10²⁰ cm⁻³.

A thickness of the intermediate layer may be 1000 nm or less.

The nitride semiconductor device may further comprise an n-type region exposed on a part of a surface of the nitride semiconductor substrate. The electrode layer may be formed to traverse across the n-type region and the p-type region. The intermediate layer may be arranged between the p-type region and the electrode layer but may not be arranged between the n-type region and the electrode layer.

The nitride semiconductor substrate may be gallium nitride. The intermediate layer may be magnesium nitride.

The description herein discloses a nitride semiconductor substrate. A magnesium concentration distribution in a direction perpendicular to a surface of the nitride semiconductor substrate may have a maximum value within a first region from the surface to a depth of 100 nanometers. The maximum value may be 1×10²⁰ cm⁻³ or more.

The magnesium concentration distribution may vary in concentration by one or more orders of magnitude within a second region extending in a depth direction from the maximum value and having a width of 100 nanometers or less.

The magnesium concentration distribution may have a singularity point, at which a concentration gradient becomes sharply smaller, in the second region. A constant concentration region may be present, in which a magnesium concentration is substantially constant in the depth direction from the singularity point. A width of the constant concentration region in the depth direction may be 50 nanometers or more.

A planar density of loop defects in a cross-sectional view of a region where magnesium is added may be 1×10⁵ [pcs/cm²] or less.

### BRIEF DESCRIPTION OF DRAWINGS

FIG. 1 is a schematic cross-sectional view of a semiconductor device 1 of a first embodiment.

FIG. 2 is a flowchart explaining a method of manufacturing the semiconductor device 1.

FIG. 3 is a cross-sectional view explaining the method of manufacturing the semiconductor device 1.

FIG. 4 is a cross-sectional view explaining the method of manufacturing the semiconductor device 1.

FIG. 5 is a cross-sectional view explaining the method of manufacturing the semiconductor device 1.

FIG. 6 is a diagram showing measurement results of current-voltage characteristics.

FIG. 7 is a schematic cross-sectional view of a semiconductor device 101 of a second embodiment.

FIG. 8 is a flowchart explaining a method of manufacturing the semiconductor device 101.

FIG. 9 is a cross-sectional view explaining the method of manufacturing the semiconductor device 101.

FIG. 10 is a schematic cross-sectional view of a semiconductor device 201 of a comparative example.

FIG. 11 is a flowchart of a method of manufacturing a nitride semiconductor substrate.

FIG. 12 is a cross-sectional view showing a manufacturing step of the nitride semiconductor substrate.

FIG. 13 is a cross-sectional view showing a manufacturing step of the nitride semiconductor substrate.

FIG. 14 is a cross-sectional view showing a manufacturing step of the nitride semiconductor substrate.

FIG. 15 is a cross-sectional view showing a manufacturing step of the nitride semiconductor substrate.

FIG. 16 is a graph showing a Mg concentration distribution profile.

FIG. 17 is an SNDM tomographic observative image of a p-type GaN region of the present embodiment.

FIG. 18 is an SNDM tomographic observative image of a p-type GaN region of the comparative example.

### DESCRIPTION OF EMBODIMENTS

### First Embodiment

### (Configuration of Semiconductor Device 1)

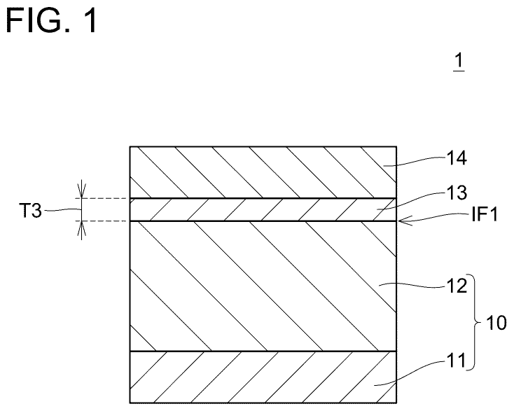

FIG. 1 shows a schematic cross-sectional view of a semiconductor device 1 of a first embodiment. The semiconductor device 1 has a structure in which a semiconductor substrate 10, an intermediate layer 13, and an electrode layer 14 are stacked in this order. The semiconductor substrate 10 has a structure in which a p-type GaN layer 12 is stacked on a GaN substrate 11. That is, the p-type GaN layer 12 is exposed over an entire surface of the semiconductor substrate 10. Impurities in the p-type GaN layer 12 are magnesium, and a concentration thereof ranges from 1×10¹⁶ to 1×10²⁰ cm³.

The intermediate layer 13 is arranged on an entire upper surface of the p-type GaN layer 12. The intermediate layer 13 is a compound containing magnesium and nitrogen. In the present embodiment, the intermediate layer 13 is magnesium nitride (MgNx). A thickness T3 of the intermediate layer 13 is 1000 nm or less, and is preferably 300 nm or less.

A concentration of nitrogen in the intermediate layer 13 decreases from an upper surface 13u of the intermediate layer 13 toward the p-type GaN layer 12. This is because the intermediate layer 13 is a layer formed by diffusing nitrogen from the upper surface 13u by annealing the magnesium layer in a nitrogen atmosphere, as will be described later.

Further, the intermediate layer 13 contains gallium, and the p-type GaN layer 12 contains magnesium. A concentration of gallium in the intermediate layer 13 decreases in as its distance from an interface IF1 between the p-type GaN layer 12 and the intermediate layer 13 increases. A concentration of magnesium in the p-type GaN layer 12 decreases as its distance from the interface IF1 increases. This is because interdiffusion is takes place at the interface IF1 by the annealing step described below.

Further, the intermediate layer 13 has an amorphous structure. This is because the intermediate layer 13 is a magnesium nitride layer formed by nitrogen annealing. The fact that the intermediate layer 13 has the amorphous structure can be confirmed by XPS (X-ray photoelectron spectroscopy).

It is also possible to form a magnesium nitride layer without using the nitrogen annealing. For example, this can be done by a method of sputtering magnesium in a nitrogen atmosphere. However, the magnesium nitride layer formed without nitrogen annealing does not have an amorphous structure, and may contain microcrystals. Moreover, its nitrogen concentration does not vary along a thickness direction. Therefore, it is possible to identify whether the intermediate layer 13 is a layer formed by the nitrogen annealing or not by analyzing the presence of the amorphous structure and a distribution of the nitrogen concentration in the thickness direction.

The electrode layer 14 is arranged over an entire upper surface of the intermediate layer 13. Structure and thickness of the electrode layer 14 are not particularly limited. In the present embodiment, the electrode layer 14 has a structure in which gold is stacked on nickel.

### (Method of Manufacturing Semiconductor Device 1)

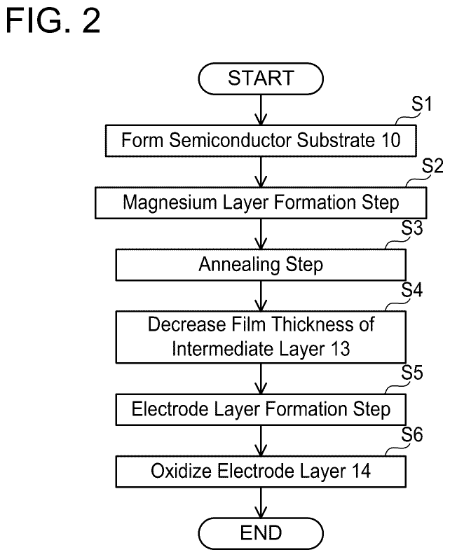

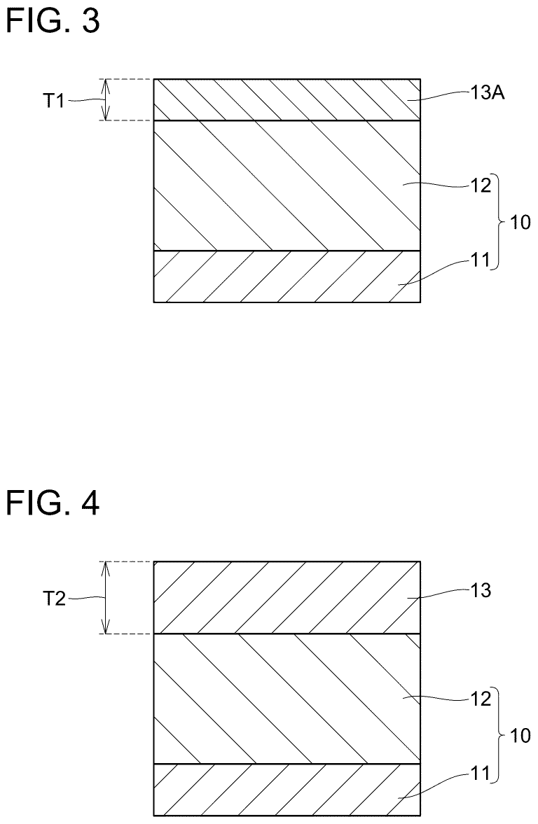

Referring to a flowchart in FIG. 2 and schematic cross-sectional views in FIGS. 3 to 5, a method of manufacturing the semiconductor device 1 will be described. In step S1, a semiconductor substrate 10 in which a p-type GaN layer 12 is stacked on a GaN substrate 11 is formed. The semiconductor substrate 10 may be formed by growing the p-type GaN layer 12 on the GaN substrate 11 by an epitaxial growth method (e.g., MOVPE, HVPE, MBE methods). In the present embodiment, the magnesium concentration of the p-type GaN layer 12 is 1×10¹⁷ cm³.

In step S2, a magnesium layer formation step is performed. Specifically, a magnesium layer 13A is formed on a surface of the p-type GaN layer 12 (see FIG. 3). The magnesium layer 13A is a layer that contains magnesium as its main component. The magnesium layer 13A may contain other elements such as fluorine and oxygen, etc. In the present embodiment, a thickness T1 of the magnesium layer 13A is 50 nm. The magnesium layer 13A may be formed using various other methods and devices. For example, an EB deposition device, a resistance heating deposition device, a sputtering device, and the like may be used.

In step S3, an annealing step is performed. Specifically, the semiconductor substrate 10 on which the magnesium layer 13A is formed is annealed in an atmosphere containing nitrogen. An annealing temperature may be in a range of 300 to 1000° C. An annealing time may be set as desired. The annealing can be performed using various methods and devices. In the present embodiment, the annealing was performed at 800° C. for 60 minutes using a rapid thermal anneal (RTA) device.

The annealing step allows nitrogen in the atmosphere to diffuse from a surface of the magnesium layer 13A. Thus, the magnesium layer 13A can be transformed into an intermediate layer 13 (magnesium nitride) (see FIG. 4). A post-anneal thickness T2 of the intermediate layer 13 is larger than the pre-anneal thickness T1. In the present embodiment, the thickness T1 was 50 nm and the thickness T2 was 80 to 100 nm. The annealing step can also cause interdiffusion to occur between the p-type GaN layer 12 and the magnesium layer 13A.

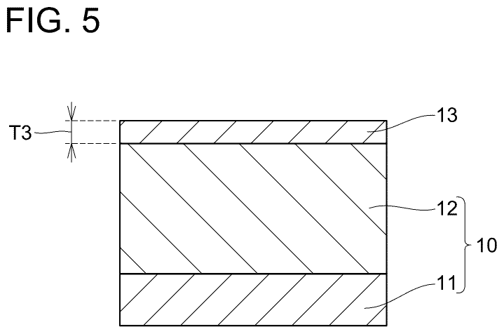

In step S4, a step of decreasing a film thickness of the intermediate layer 13 is performed. As a result, the film thickness of the intermediate layer 13 is reduced from the thickness T2 (FIG. 4) to a thickness T3 (FIG. 5). This process can be performed by various methods such as wet etching using aqua regia, hydrofluoric acid, etc., dry etching, polishing, etc. In the present embodiment, the thickness T2 (80 to 100 nm) was reduced to T3 (about 20 nm) by wet etching with aqua regia.

In step S5, an electrode layer formation step is performed. Specifically, an electrode layer 14 is formed on an upper surface of the intermediate layer 13 after the film thickness is reduced. In the present embodiment, the electrode layer 14 has a structure in which nickel and gold are stacked in this order.

In step S6, the semiconductor device 1 with the electrode layer 14 is annealed in an oxygen atmosphere. Due to this, a contact constituted of nickel oxide can be formed. In the present embodiment, this annealing was performed at 525° C. for 5 minutes. The semiconductor device 1 shown in FIG. 1 is thereby completed.

### (Measurement Results of Current-Voltage Characteristics)

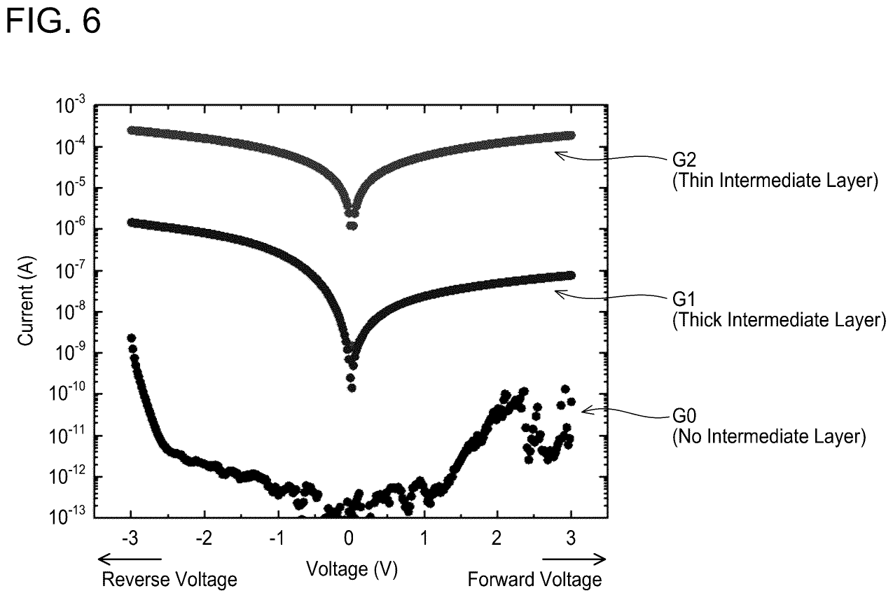

Current-voltage characteristics between the p-type GaN layer 12 and the electrode layer 14 were measured. An impurity concentration of the p-type GaN layer 12 was 1×10¹⁷ cm³. FIG. 6 shows measurement results thereof. A horizontal axis shows the voltage. A case of applying a positive voltage to the electrode layer 14 with respect to the p-type GaN layer 12 is considered as a forward voltage. A case of applying a positive voltage to the p-type GaN layer 12 with respect to the electrode layer 14 is considered as a reverse voltage. A vertical axis is the current.

A graph G0 shows measurements in a semiconductor device of a comparative example. The semiconductor device of the comparative example has a structure in which the electrode layer 14 is directly arranged on the p-type GaN layer 12 without the intermediate layer 13. Graphs G1 and G2 are measurements in the semiconductor device of the present embodiment. The graph G1 shows the measurements in the semiconductor device in which the electrode layer 14 is arranged on a thick intermediate layer 13 (FIG. 4, thickness T2). The graph G2 shows the measurements for the semiconductor device in which the electrode layer 14 is arranged on a thin intermediate layer 13 (FIG. 1, thickness T3).

As can be seen from the graphs G0 and G1, the current value can be increased up to one million times in the semiconductor device of the present embodiment as compared to the semiconductor device of the comparative example. That is, a contact resistance can significantly be reduced by providing the intermediate layer 13. Further, as can be seen from the graphs G1 and G2, by configuring the intermediate layer 13 thinner, the current value can further be increased up to 1,000 times. That is, by thinning the intermediate layer 13, it is possible to further reduce the contact resistance.

Further, in the graph G1, the current value of the reverse voltage is about 10 times higher than the current value of the forward voltage. On the other hand, in the graph G2, the current value of the reverse voltage and the current value of the forward voltage are almost equal. That is, by thinning the intermediate layer 13, a rectifying effect can be suppressed. It becomes possible to form an excellent ohmic contact.

The following explains a model case in which the contact resistance can be reduced by interposing the intermediate layer 13. In gallium nitride, which is a compound semiconductor, p-type gallium nitride has many defects, and this causes band bending on a material surface. Therefore, a hole energy barrier for holes becomes high. Therefore, in the art disclosed herein, magnesium can be diffused to the surface of the p-type GaN layer 12 by depositing and annealing the magnesium layer 13A on the p-type GaN layer 12. The degree of band bending can be reduced by terminating defects in gallium nitride with magnesium and by increasing the acceptor concentration. This can reduce the hole energy barrier. Further, in the art disclosed herein, the electrode layer 14 is formed on the intermediate layer 13. Due to this, the electrode can be formed while maintaining a state of having reduced the hole energy barrier. As a result, the contact resistance can be reduced.

### Effects

Conventionally, it has been difficult to reduce a contact resistance or to form an ohmic contact with an electrode formed on a p-type GaN layer with a low impurity concentration (about 1×10¹⁶ to 1×10²¹ cm⁻³). This is because a p-type GaN layer with a high concentration (2×10¹⁹ cm⁻³ or more) must be interposed between the low concentration p-type GaN layer and the electrode. Further, this is also because if the high-concentration p-type GaN is formed by epitaxial regrowth, a Si pile-up layer would be introduced at an interface of the regrown layer. In the art disclosed herein, the intermediate layer 13 (magnesium nitride) formed by the nitrogen annealing is arranged between the low concentration p-type GaN layer and the electrode. Due to this, the contact resistance with the electrode can be reduced for the low concentration p-type GaN layer, and the ohmic contact can be realized. In addition, since there is no need to re-grow p-type GaN with high concentration, man-hour and cost can be reduced.

### Second Embodiment

### (Configuration of Semiconductor Device 101)

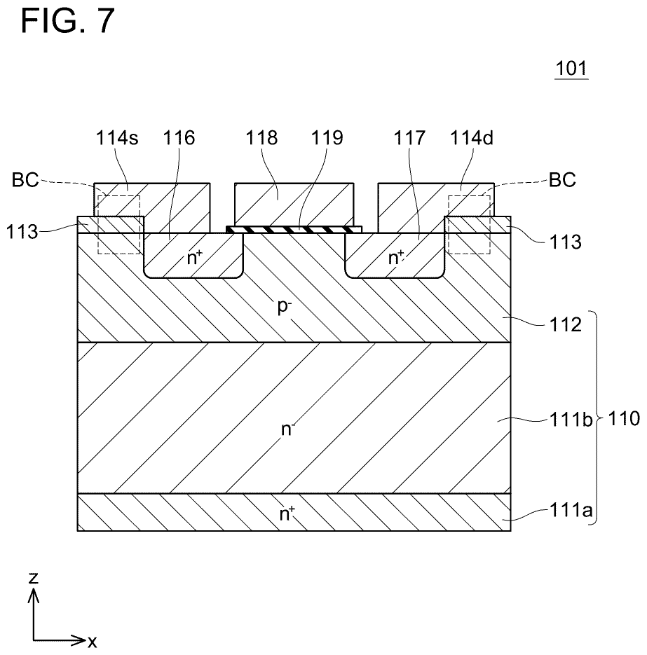

FIG. 7 shows a schematic cross-sectional view of a semiconductor device 101 of a second embodiment. The semiconductor device 101 is a horizontal MOSFET with a planar gate. The semiconductor device 101 has a semiconductor substrate 110. The semiconductor substrate 110 has a structure in which a drain layer 111a, which is a high concentration n-type (n⁺ type) GaN, a drift layer 111b, which is a low concentration n-type (n⁻ type) GaN, and a body layer 112, which is a low concentration p-type (p⁻ type) GaN, are stacked. In the present embodiment, a magnesium concentration of the body layer 112 is set to 1×10¹⁸ cm⁻³.

N-type GaN source region 116 and drain region 117 are arranged at upper portions of the body layer 112. The source region 116 and the drain region 117 are regions formed by ion implantation, and are regions that are exposed at portions of a surface of the semiconductor substrate 110. A gate insulating film 119 and a gate electrode 118 are disposed in a region between the source region 116 and the drain region 117. The gate electrode 118 is disposed on the upper surface of the body layer 112 via the gate insulating film 119.

Of the body layer 112 that is exposed on the surface of the semiconductor substrate 110, an intermediate layer 113 is disposed in an area where the gate insulating film 119 is not disposed. A structure of the intermediate layer 113 is the same as that of the intermediate layer 13 of the first embodiment, so the description thereof is omitted.

A source electrode 114s is in contact with an upper surface of the source region 116 and an upper surface of the intermediate layer 113. That is, the source electrode 114s is disposed to traverse across the source region 116 and the body layer 112. The intermediate layer 113 is disposed between the source electrode 114s and the body layer 112. On the other hand, the intermediate layer 113 is not disposed between the source electrode 114s and the source region 116. A body contact BC is formed by the contact region between the source electrode 114s and the body layer 112. Since the function of the body contact BC is well known, the description thereof is omitted.

Similarly, a drain electrode 114d is disposed to traverse across the drain region 117 and the body layer 112. An intermediate layer 113 is disposed between the drain electrode 114d and the body layer 112. On the other hand, the intermediate layer 113 is not disposed between the drain electrode 114d and the drain region 117. A body contact BC is formed by a contact area between the drain electrode 114d and the body layer 112.

### (Method of Manufacturing Semiconductor Device 101)

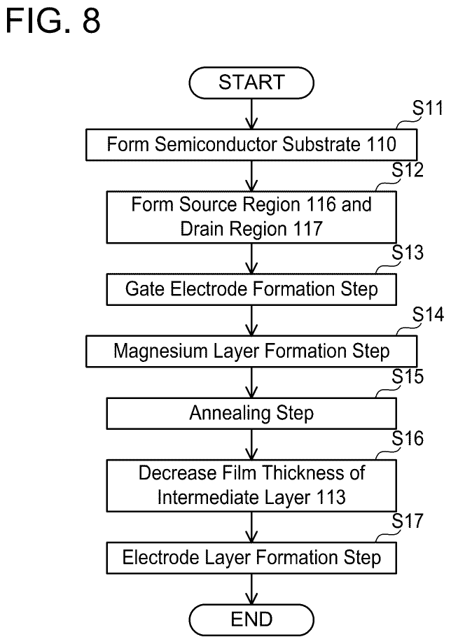

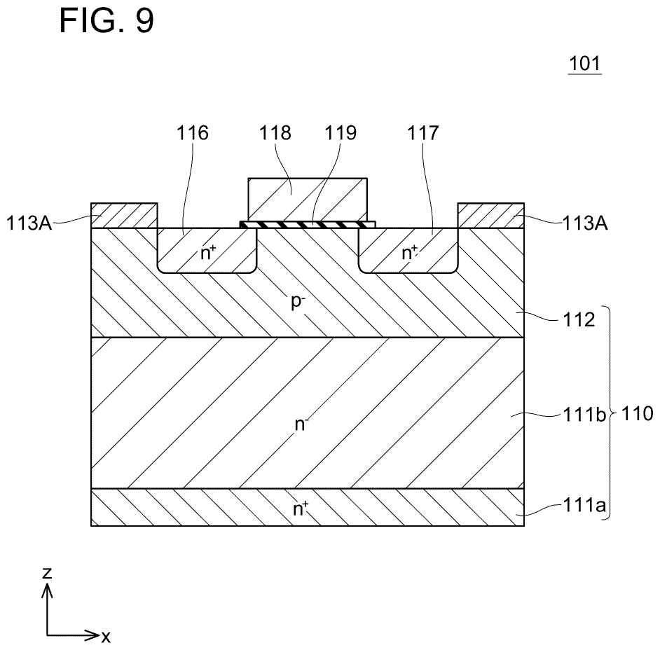

Referring to a flowchart of FIG. 8 and a schematic cross-sectional view of FIG. 9, a method of manufacturing the semiconductor device 101 will be described. In step S11, a semiconductor substrate 110 is formed. Specifically, a drift layer 111b and a body layer 112 are epitaxially grown on a drain layer 111a. In step S12, a source region 116 and a drain region 117 are formed. Specifically, silicon or germanium is ion-implanted into the body layer 112 via a mask with openings corresponding to the source region 116 and drain region 117.

In step S13, a gate electrode formation step is performed. Specifically, a gate electrode 118 is formed via a gate insulating film 119 in a region between the source region 116 and the drain region 117 and on an upper surface of the body layer 112. The gate insulating film 119 is an insulating film formed by depositing SiO₂ or Al₂O₃ or the like by an atomic layer deposition method or the like. The gate electrode 118 is polysilicon doped with impurities such as boron. The gate electrode 118 can be formed using a well-known photolithography technique and dry etching process.

In step S14, a magnesium layer formation step is performed. Specifically, a mask layer with an opening corresponding to a specific region is formed. The specific region is an area where the magnesium layer 113A is to be formed. In the present embodiment, the specific region is an area where the body contact BC is formed. Next, magnesium is deposited via the mask layer. Finally, the mask layer is removed. Due to this, a magnesium layer 113A is selectively formed on a surface of the body layer 112, as shown in FIG. 9. The magnesium layer 113A is not formed on surfaces of the source region 116 and the drain region 117. A structure of the magnesium layer 113A is the same as that of the magnesium layer 13A of the first embodiment, so the description therefor will be omitted.

In step S15, an annealing step is performed. Specifically, the semiconductor substrate 110 on which the magnesium layer 113A is formed is annealed in an atmosphere containing nitrogen. Since contents of the annealing step are the same as those in step S3 of the first embodiment, the description thereof will be omitted. This allows the magnesium layer 113A to be changed into the intermediate layer 113, which is magnesium nitride. The structure of the intermediate layer 113 is the same as that of the intermediate layer 13 in the first embodiment, so the description thereof will be omitted.

In step S16, a process of decreasing a thickness of the intermediate layer 113 is performed. Contents of this process are the same as those in step S4 of the first embodiment, so the description thereof will be omitted.

In step S17, an electrode formation step is performed. Specifically, a metal layer is deposited. Then, the metal layer is processed into a source electrode 114s and a drain electrode 114d using a well-known photolithography technique and dry etching process. The source electrode 114s is formed to traverse across the intermediate layer 113 and the source region 116 in the body layer 112. The drain electrode 114d is also formed to traverse across the intermediate layer 113 and the drain region 117 formed in the body layer 112. Due to this, the semiconductor device 101 as shown in FIG. 7 is completed.

### Effects

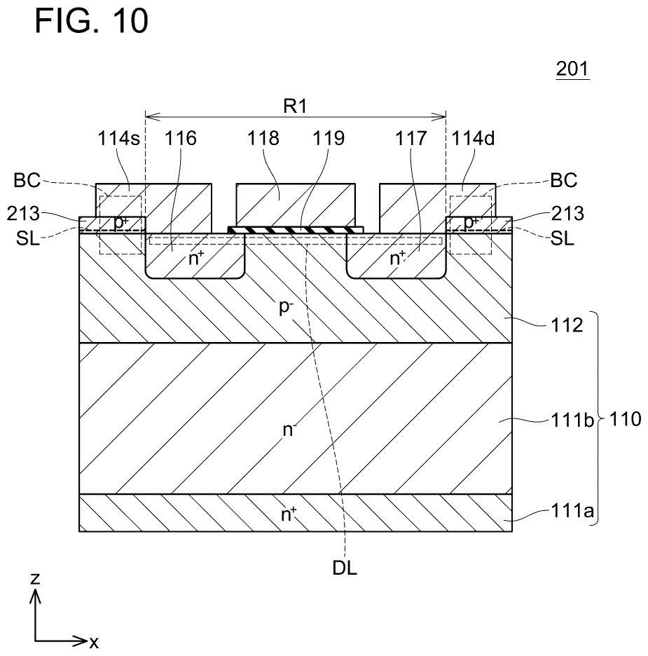

A technical problem will be explained using a semiconductor device 201 of a comparative example in FIG. 10. The semiconductor device 201 of the comparative example differs from the semiconductor device 101 of the second embodiment (FIG. 7) in that the intermediate layer 113 is substituted with a contact layer 213. The contact layer 213 is a high concentration p-type (p⁺ type) GaN layer. Common parts are given the same reference signs and descriptions thereof will be omitted. A body layer 112 of a MOSFET needs to control its magnesium concentration (e.g., about 1×10¹⁶ to 1×10²¹ cm³) due to its threshold voltage. As such, the high concentration p-type GaN layer (contact layer 213) must be interposed to reduce a contact resistance of a body contact BC and to form an ohmic contact. A general method for forming this contact layer 213 is to regrow the contact layer 213 over an entire surface of the body layer 112 and then remove the contact layer 213 in an opening region R1 by dry etching. However, the regrowth introduces a Si pile-up layer SL at an interface between the contact layer 213 and the body layer 112. Therefore, it is difficult to lower the contact resistance of the body contact BC and to form ohmic contact. Further, device characteristics could be degraded because a damaged layer DL is formed in a channel by dry etching.

In the semiconductor device 101 of the present embodiment (FIG. 7), the intermediate layer 113 (magnesium nitride) is arranged in the region where the body contact BC is formed. Since the re-growth of the high concentration p-type GaN layer is unnecessary, the Si pile-up layer SL is not formed. It thus becomes possible to lower the contact resistance of the body contact BC and to form ohmic contact. Further, by using the lithography technique, the intermediate layer 113 can be selectively formed in the area where the body contact BC is formed. Since the process of removing the intermediate layer 113 by dry etching is unnecessary, the damaged layer DL is not formed in the channel. Degradation of the device characteristics can be suppressed.

Further, the intermediate layer 113 (magnesium nitride) also increases the contact resistance for n-type GaN. In the semiconductor device 101 of the present embodiment (FIG. 7), the intermediate layer 113 is not arranged between the source region 116 and the source electrode 114s, and between the drain region 117 and the drain electrode 114d. Due to this, the increase in the contact resistance can be suppressed.

### Third Embodiment

(Method of Forming p-Type GaN Region)

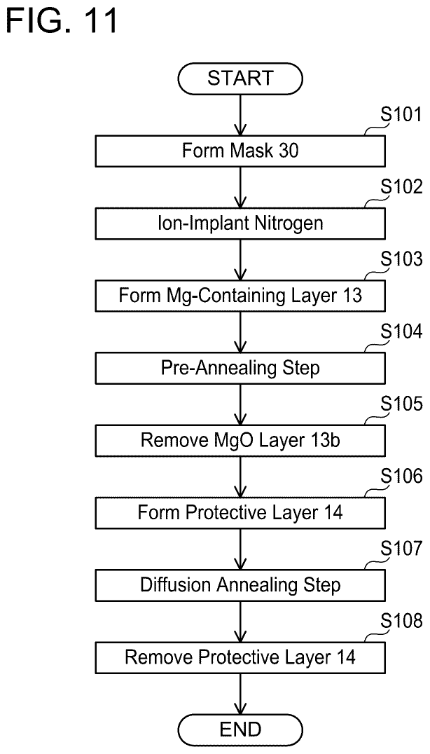

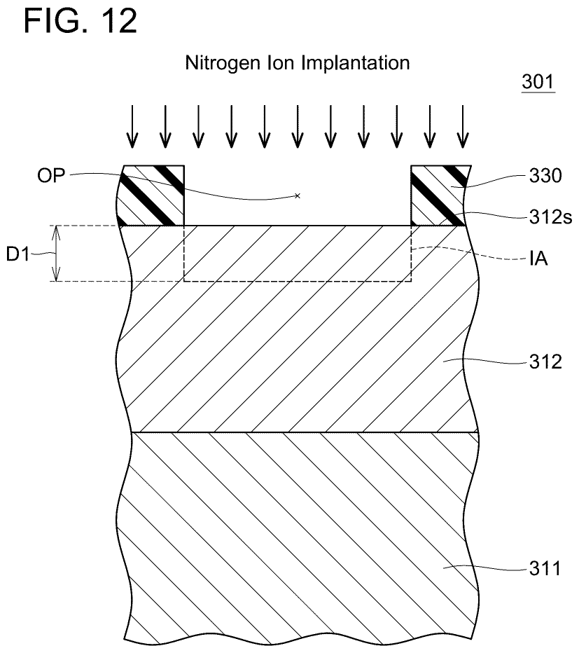

The present embodiment describes a case in which gallium nitride (GaN) is used as a nitride semiconductor, magnesium (Mg) is used as a group II element acceptor impurity, and silicon (Si) is used as a donor impurity. A flowchart in FIG. 11 and cross-sectional views in FIGS. 12 to 15 are used to explain steps of forming a p-type region on a substrate 301. FIGS. 12 to 15 show partially enlarged views of a surface of the substrate 301 and a vicinity thereof. The substrate 301 has a structure in which a GaN layer 312, which is not doped with impurities, is stacked on a GaN base substrate 311. The GaN layer 312 may be formed by epitaxial growth. In the present embodiment, a thickness of the GaN layer 312 is 3 km.

In step S101, a mask 330 is formed on a surface 312s of the GaN layer 312. The mask 330 has an opening OP corresponding to a position where a p-type region is to be formed. The mask 330 can be formed by a known photolithography technique.

In step S102, nitrogen is ion-implanted from the surface 312s via the mask 330 (see FIG. 12). Nitrogen ion implantation is performed so that a nitrogen concentration from the surface 312s to a predetermined depth is approximately constant, in a so-called box profile. The box profile can be achieved by performing the ion implantation multiple times with different levels of implantation energy and amount. Due to this, a nitrogen ion-implanted implantation region IA is formed. In FIG. 12, the implantation region IA is shown as a dotted line. In the present embodiment, a depth D1 of the implantation region IA is 250 nm. An acceleration voltage of nitrogen ions was in a range of 10 KV to 10 MV. The nitrogen concentration was set to three types, namely 5×10¹⁹ cm⁻³, 5×10¹⁸ cm⁻³, and 5×10¹⁶ cm⁻³.

A reason for ion implanting nitrogen will be explained. Ion implantation forms crystal defects such as Ga vacancies and nitrogen vacancies. The Ga vacancies are necessary, because the substitution of Mg with the Ga vacancies activates Mg and thus imparts the p-type characteristic. On the other hand, the nitrogen vacancies are donor defects and thus inhibit formation of the p-type characteristics by compensating acceptors. Therefore, it is desirable to have fewer nitrogen vacancies. Therefore, in the art disclosed in the present embodiment, nitrogen, which constitutes the nitride semiconductor, is ion implanted. Since the nitrogen vacancies formed by the ion implantation are substituted by the implanted nitrogen, generation of the nitrogen vacancies can be suppressed. Therefore, the Ga vacancies can be selectively formed by nitrogen ion implantation.

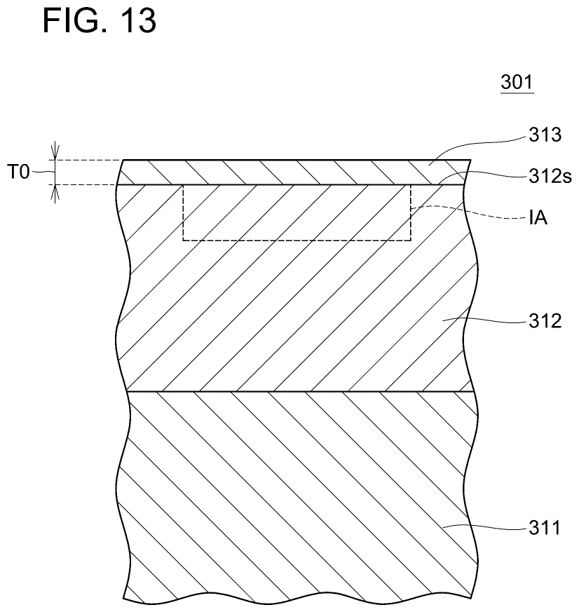

In step S103, an Mg-containing layer 313 is formed on the surface 312s (see FIG. 13). The Mg-containing layer 313 is a layer containing Mg. In the present embodiment, the Mg-containing layer 313 was formed by depositing Mg by electron beam (EB) deposition. Further, a thickness TO of the Mg-containing layer 313 was 50 nm.

In step S104, a pre-annealing step is performed. In the present embodiment, this step is performed at 800° C. for 1 hour using a Rapid Thermal Anneal (RTA) device. The pressure and atmosphere used in the pre-annealing are not particularly limited. In the present embodiment, the pre-annealing was performed in an atmospheric atmosphere at ambient pressure.

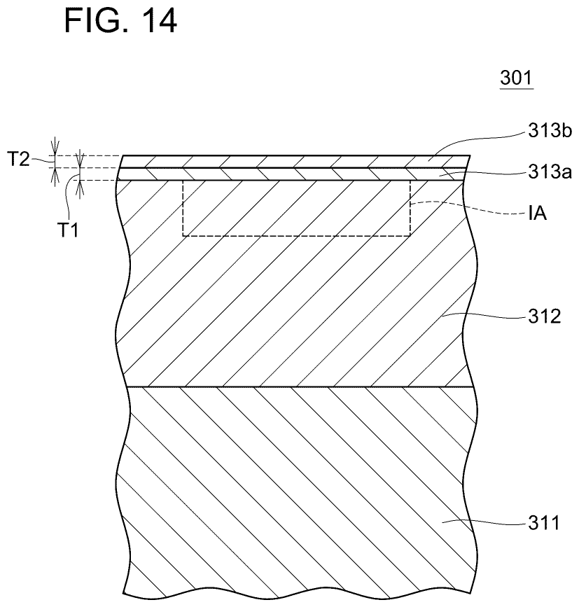

The pre-annealing step can transform the Mg-containing layer 313 (FIG. 13) into a stacked structure of Mg solid layer 313a and MgO layer 313b (FIG. 14). The Mg solid layer 313a is a layer containing Mg, Ga, and N. A chemical composition of the Mg solid layer 313a is not particularly limited. For example, the composition may be a mixture of magnesium nitride (MgN) and GaN. The MgO layer 313b is a layer containing magnesium oxide. The MgO layer 313b is an altered layer formed by the surface of the Mg containing layer 313 reacting with oxygen in an annealing atmosphere. In the present embodiment, a thickness T1 of the Mg solid layer 313a and the thickness T2 of the MgO layer 313b ranged from 20 to 50 nm.

The thickness T1 of the Mg solid layer 313a can be controlled by the thickness TO of the Mg-containing layer 313 and a temperature of the pre-annealing step. For example, by decreasing the thickness TO of the Mg-containing layer 313, the thickness T1 of the Mg solid layer 313a can be decreased; the thickness T1 of the Mg solid layer 313a can control the doping concentration of Mg, which is described later. For example, by decreasing the thickness T1 of the Mg solid layer 313a, the source of Mg can be reduced and thus the doping concentration of Mg can be reduced.

In step S105, the MgO layer 313b formed on the surface of the Mg solid layer 313a is removed. the oxygen in the MgO layer 313b functions as a donor impurity to the GaN. Therefore, by removing the MgO layer 313b, it is possible to prevent the p-type characteristics from being inhibited by the oxygen. The removal method may be wet etching, dry etching, polishing, or various other methods. In this specification, the removal was performed by wet etching using aqua regia.

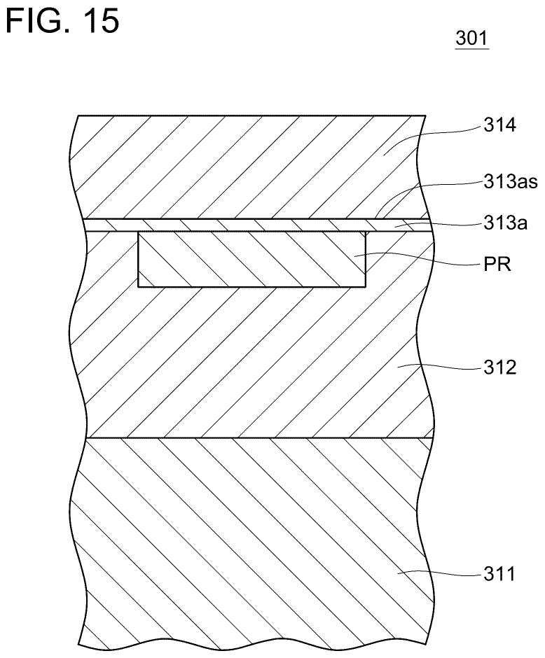

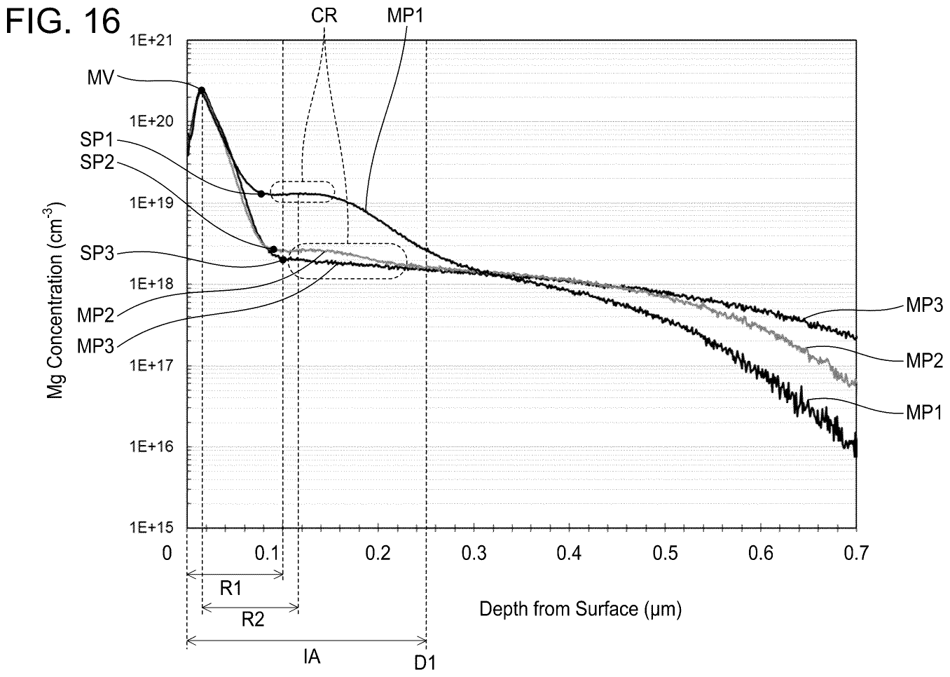

In step S106, a protective layer 314 is formed on a surface 313as of the Mg solid layer 313a from which the MgO layer 313b has been removed (see FIG. 15). The protective layer 314 preferably has high heat resistance and adhesiveness. The protective layer 314 can suppress nitrogen desorption from GaN in the diffusion annealing step described below. In this embodiment, the protective layer 314 is aluminum nitride (AlN) deposited by a MOVPE method. A thickness thereof is 300 nm.

In step S107, a diffusion annealing step is performed. A temperature of the diffusion annealing step is higher than the temperature of the pre-annealing step in step S104. For example, it may be in the range of 700° C. to 1400° C. An annealing atmosphere is not particularly limited. The annealing atmosphere may include nitrogen. Due to this, an effect of suppressing thermal decomposition of the protective layer 314 and GaN can be achieved. A pressure may be 1000 atmospheres or less. An annealing time may be determined according to a Mg concentration distribution profile described below, and may range from 30 seconds to 1 hour, for example. From the perspective of thermal budgeting, the annealing time may be correlated such that the higher the temperature is, the shorter the annealing time becomes. For example, for a case of 1400° C., the annealing time may be 30 seconds, and the annealing time may be 1 hour for a case of 700° C. In the present embodiment, annealing was performed at 1300° C. in an atmospheric atmosphere at ambient pressure. Further, the annealing time was 5 minutes.

In the implantation region IA, crystal defects are formed in a box profile. Further, an Mg diffusion rate can be increased in the region where the crystal defects are formed as compared to the region where no crystal defects are formed. Therefore, the diffusion annealing step can diffuse Mg from the Mg solid layer 313a to the entire implantation region IA in a solid phase. As mentioned above, since the Ga vacancies are selectively formed in the implantation region IA by the nitrogen ion implantation, the Ga vacancies can be activated by substituting Mg therein. As a result, a p-type GaN region PR can be formed in the region where the implantation region IA was formed (see FIG. 15).

In step S108, the protective layer 314 is removed. The removal method may vary, such as wet etching or dry etching. In this description, it is removed by wet etching using TMAH (tetramethyl ammonium hydroxide). A formation flow for the p-type GaN region is thereby completed.

### (Mg Concentration Distribution Profile)

The following describes the Mg concentration distribution profile in the depth direction on the substrate 301 prepared by the flow described above. FIG. 16 shows the Mg concentration distribution profile using secondary ion mass spectrometry (SIMS). A vertical axis is the Mg concentration. A horizontal axis is a depth of the GaN layer 312 from the surface 312s.

The implantation region IA is an area where nitrogen ions are implanted in a box profile. In the present embodiment, the depth D1 of the implantation region IA is about 250 nm. Mg concentration distribution profiles MP1 to MP3 show Mg concentration distributions in a direction perpendicular to the surface 312s. The Mg concentration distribution profiles MP1 to MP3 show profiles that are formed when the nitrogen concentration in the implantation region IA is 5×10¹⁹ cm⁻³, 5×10¹⁸ cm⁻³, and 5×10¹⁶ cm⁻³, respectively.

The Mg concentration distribution profiles MP1-MP3 have a maximum value MV of Mg concentration within the first region R1 from the surface to a depth of 100 nm. The maximum value MV is greater than 1×10²¹ cm⁻³. The depth of the region with the maximum value MV from the surface 312s is about 15 nm. The effect will be explained below. Conventionally, when using the ion implantation method, it has been difficult to achieve a high Mg concentration of 1×10²¹ cm⁻³ or higher at a top surface that is about 15 nm from the surface 312s. With the art disclosed herein, Mg is solid-phase diffused from the surface 312s, so the Mg concentration at the top surface can be as high as 1×10²¹ cm³ or more. This enables an ohmic contact to be formed with the electrode formed on the surface 312s.

In the Mg concentration distribution profiles MP1 to MP3, the Mg concentration varies by one or more orders of magnitude within the second region R2, which has a width of less than 100 nm extending from the maximum value MV in the depth direction. In other words, the Mg concentration decreases to 1/10 or less of the maximum MV value as the depth increases from the maximum MV value (depth of about 15 nm). Further, the Mg concentration distribution profiles MP1 to MP3 have singularity points SP1 to SP3 in the second region R2, where the concentration gradient becomes sharply smaller. Further, in the depth direction from the singularity points SP1 to SP3, a constant concentrate ion region CR in which the Mg concentration is substantially constant is present. A width of the constant concentration region CR in the depth direction is 50 nm or more. From the above, it can be seen that the Mg concentration in the depth direction can be reduced steeply. The effect will be explained. When the Mg concentration distribution profile varies moderately in the depth direction, a low concentration p-type region exists at the bottom of the p-type region. The low-concentration p-type region becomes a high-resistance region when forming a pn junction surface. On the other hand, in the art disclosed herein, the Mg concentration distribution profile can be made steep, thus there are no low-concentration p-type regions at the bottom of the p-type region. Therefore, a pn junction surface where a high concentration p-type region and a high concentration n-type region meet can be created. Formation of high resistance regions can be suppressed on the pn junction surface.

As can be seen from the Mg concentration distribution profile MP1, the Mg concentration is higher in the implantation region IA (shallower than 0.25 m) than in the region deeper than 0.25 m. This is because Mg can be captured by the crystal defects formed by the nitrogen ion implantation. As such, the desired Mg concentration distribution profile can be formed by forming the implantation region IA in the region where the Mg concentration is to be set higher. Further, as can be seen from a comparison of the Mg concentration distribution profiles MP1 (nitrogen concentration 5×10¹⁹ cm³), MP2 (nitrogen concentration 5×10¹⁸ cm⁻³), and MP3 (nitrogen concentration 5×10¹⁶ cm⁻³), a higher nitrogen concentration in the implantation region IA enables the Mg concentration to be higher. This is because a higher nitrogen concentration enables a higher crystal defect density to be realized. Therefore, the Mg concentration can be indirectly controlled by controlling the nitrogen concentration.

### Effects

When Mg is diffused by the solid phase diffusion, the Mg concentration distribution profile in the depth direction and the Mg doping concentration are considered as so-called error function profiles. It is difficult to control the Mg concentration distribution profile and doping concentration, since they are uniquely determined by thermal treatment temperature and time. As such, it is difficult to form the box profile required for various devices and to adjust the Mg concentration to the desired value. In addition, in order to diffuse Mg deeper than 100 nm, a long thermal treatment time of several hours or more is required. Therefore, the art disclosed in the present embodiment has the configuration in which Mg is solid-phase diffused into the implantation region IA where the crystal defects are formed. Since Mg can be captured and activated in the Ga vacancies, the Mg concentration distribution profile can be formed to follow the nitrogen profile of the implantation region IA. Further, the Mg doping concentration can be set higher by increasing the concentration of implanted nitrogen. In other words, the Mg concentration distribution profile can be controlled by controlling the nitrogen profile of the implanted region IA, and the Mg doping concentration can be controlled by controlling the nitrogen concentration. Further, since it is easier to diffuse Mg in the region where defects are formed than in the region where defects are not formed, the thermal treatment time to diffuse Mg into the region deeper than 100 nm can be significantly reduced (e.g., 5 minutes).

Conventionally, to form p-type GaN regions by Mg ion implantation, thermal treatment under an ultra-high pressure was required to recover nitrogen vacancies and other damages inside the crystal. However, this was difficult to perform because it required the thermal treatment under an extremely special environment of 1 GPa (approximately 10,000 atmospheres) of pressure. In the art disclosed herein, since the implantation region IA is formed by the nitrogen ion implantation, it is possible to actively form the Ga vacancies while suppressing the generation of the nitrogen vacancies. Since the nitrogen vacancies and other damages can be suppressed, a thermal treatment at a very high pressure can be made unnecessary. The thermal treatment can easily be performed.

(Evaluation Results of p-Type GaN Region)

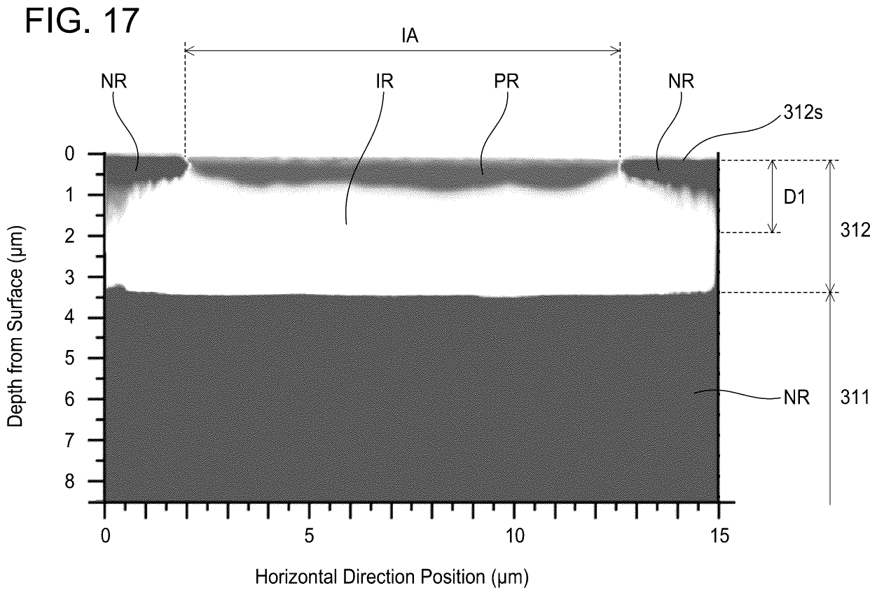

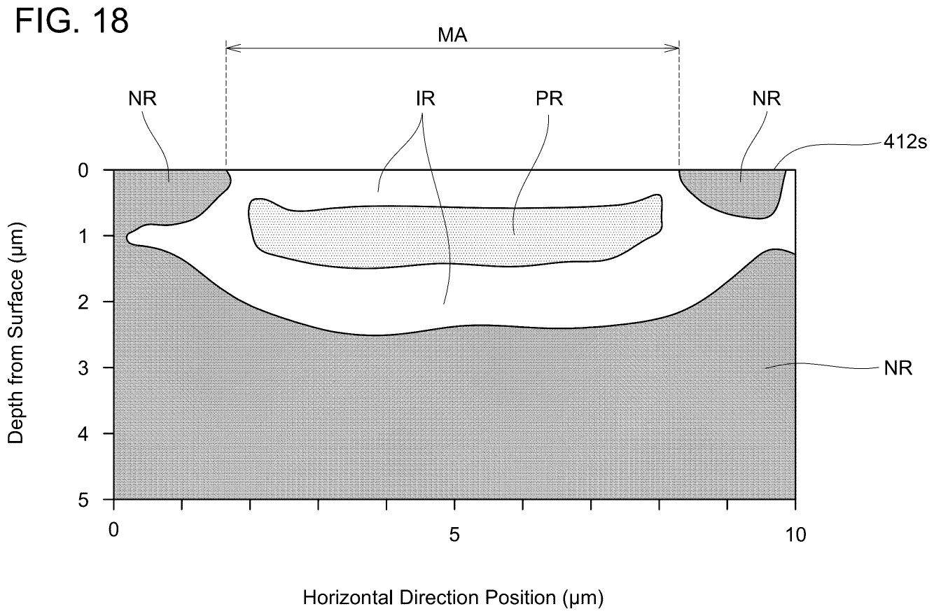

The formation state of the p-type GaN region was evaluated using a scanning nonlinear dielectric constant microscope (SNDM). The SNDM is a microscope that visualizes carrier distribution in two dimensions. FIGS. 17 and 18 show examples of tomographic observation results. A vertical axis is the depth from the substrate surface. A horizontal axis is a position in a direction horizontal to the surface. In FIGS. 17 and 18, a p-type GaN region PR is shown in light fill, an n-type GaN region NR is shown in dark fill, and a high-resistance intrinsic GaN region IR is shown in white.

FIG. 17 shows a cross-sectional view of a p-type GaN region formed by the art disclosed in the present embodiment. An undoped GaN layer 312 of about 3 μm is formed on a (0001) surface of an n⁺-GaN base substrate 311. An implantation region IA is formed in an upper portion of the GaN layer 312. A horizontal width of the implantation region IA is about 10.5 m, and a depth D1 is about 200 nm. Nitrogen is implanted into the implantation region IA in a box profile, and the nitrogen concentration is 5×10¹⁸ cm³.

In the present embodiment of FIG. 17, a p-type GaN region PR is formed in the region from the surface 312s to a depth of about 0.7 μm inside the implantation region IA. Since the surface 312s is p-type, it is possible to form an ohmic contact when an electrode is formed on the implantation region IA. An n-type GaN region NR is formed outside the implantation region IA from the surface 312s to a depth of about 1.0 m. An intrinsic GaN region IR is formed in the region from about 0.5 μm to 3.0 μm in depth.

On the other hand, FIG. 18 shows a comparative example. The comparative example is a cross-sectional view of a p-type GaN region formed by performing ultra-high pressure annealing (UHPA) after Mg ion implantation. In the comparative example in FIG. 18, a Mg-implanted region MA is formed in an upper portion of an n⁺-GaN substrate, where Mg is ion implanted. A p-type GaN region PR is formed in the region from about 0.5 μm to 2.0 μm in depth within the Mg-implanted region MA. However, a region from a surface 412s to about 0.5 μm is an intrinsic GaN region IR. That is, it can be understood that it is difficult to form the surface 412s by p-type GaN using the ion implantation method. As such, it is difficult to form an ohmic contact even if an electrode is formed on the Mg-implanted region MA.

### (Evaluation Result of Crystal Defects)

A formation state of the crystal defects was evaluated using annular dark-field scanning transmission electron microscopy (ADF-STEM). As a comparative example, p-type GaN regions were created by Mg ion implantation followed by ultra-high pressure annealing (1 GPa, 1480° C., 5 min). Then, a cross section of a (11-20) plane was observed. In the comparative example, many vacancy-type dislocation loop defects were observed, and their planar density was about 3×10¹⁰ [pcs/cm²].

On the other hand, when a same cross section was observed in the p-type GaN region created by the art disclosed in the present embodiment, no dislocation loop defects, such as oval shapes or coffee bean type defects caused by vacancy type defects, were observed. In other words, a loop defect density in the Mg-doped region was less than 1×10⁵ [pcs/cm²]. A reason thereof will be described. Dislocation loop defects are formed when supersaturated point defects (vacancies, interstitial atoms) gather in a planar shape and form closed dislocations at their edges. In the comparative example, numerous nitrogen vacancies are formed by the Mg ion implantation, which results in the formation of many dislocation loop defects. On the other hand, in the art disclosed in the present embodiment, the nitrogen ion implantation is used instead of the Mg ion implantation. As mentioned above, the nitrogen ion implantation can suppress the formation of the nitrogen vacancies, and thus suppresses the formation of the dislocation loop defects.

### Fourth Embodiment

In the third embodiment, a configuration in which Mg is solid phase diffused into the implantation region IA was described. In a fourth embodiment, a configuration in which Mg is vapor-phase diffused into the implantation region IA will be described. Since the steps of forming the implantation region IA (steps S101 to S102) are same, description thereof will be omitted.

In a gas phase diffusion step, a substrate 301 on which the implantation region IA is formed is annealed in an atmosphere containing Mg. The type of gas-phase Mg feedstock may vary. It may be Mg vapor or magnesium chloride (MgCl₂). It can also be various metal organic compounds (MO), such as Cp₂Mg or EtCp₂Mg. Nitrogen may also be included in the annealing atmosphere. For example, ammonia or nitrogen gas may be supplied to a chamber. Supplying nitrogen from the atmosphere to the GaN substrate can suppress occurrence of a nitrogen loss from GaN caused by annealing. In the present embodiment, annealing was performed at 830° C. in an atmosphere containing Cp₂Mg and ammonia.

After the gas phase diffusion step, a protective layer 314 may be formed (step S106), and a diffusion annealing step (step S107) and removal of the protective layer 314 (step S108) may be performed. Due to this, the formation flow of p-type GaN region by gas phase diffusion is completed.

### Effects

In the solid phase diffusion of the third embodiment, a surface morphology of the surface 312s after the formation of the p-type GaN region was degraded. For example, when a root mean square roughness (RMS) of the surface 312s was measured using AFM, etc., the RMS after nitrogen ion implantation (step S102) was 0.2 to 0.5 nm. On the other hand, the RMS after p-type GaN region completion (step S108) was 7.0 nm. This is thought to be due to the degradation of the surface morphology that occurred during the formation of the Mg solid layer 313a in the pre-annealing step (step S104).

On the other hand, in the gas phase diffusion of the fourth embodiment, the process of forming the Mg solid layer 313a can be omitted, and the surface morphology of the surface 312s can be improved. For example, the RMS after completion of the p-type GaN region was measured to be 0.3 nm. In addition, steps were observed in the AFM image of the surface 312s, indicating that the surface remained atomically flat. This enables to improve various characteristics of the substrate 301 when applied to devices.

### Fifth Embodiment

In a fifth embodiment, a configuration in which a liquid phase diffusion of Mg into the implantation region IA is performed will be described. The steps of forming the implantation region IA (steps S101 to S102) are same, so the description thereof will be omitted.

In a liquid phase diffusion step, a substrate 301 on which the injection area IA is formed is brought into contact with a melt containing Mg. The type of melt can vary. For example, the melt may be a Zn—Mg binary metal, an Al—Zn—Mg ternary metal, a Cu—Mg—Zn ternary metal, etc. Alternatively, it may be a melt of a metal with high nitrogen solubility, or an alkaline metal melt such as Na. In the present embodiment, a MgZn melt with a Mg:Zn ratio of 51:20 was used. Further, a temperature was set at 450° C.

A device configuration for performing the liquid phase diffusion step may vary. A melt may be generated in a crucible under a high temperature (e.g., 400 to 1000° C.) and high pressure (e.g., several tens of atmospheres), and the substrate 301 may be brought into contact with the melt. Further, Nitrogen gas (N₂) may be dissolved into the melt to inhibit nitrogen loss from the GaN.

After the liquid phase diffusion step, a protective layer 314 may be formed (step S106), and a diffusion annealing step (step S107) and removal of the protective layer 314 (step S108) may be performed. This completes the formation flow of p-type GaN region by liquid phase diffusion.

### Sixth Embodiment

In a sixth embodiment, a configuration in which plasma doping of Mg into the implantation region IA is performed will be described. The steps of forming the implantation region IA (steps S101 to S102) are same, so the description thereof will be omitted.

In a plasma doping step, a substrate 301 on which the implantation region IA is formed is set on a bias electrode in a vacuum vessel. Plasma of a gas containing Mg is then generated, and Mg can be introduced into the implantation region IA by accelerating Mg ions in the plasma toward a surface 312s.

After the plasma doping step, a protective layer 314 may be formed (step S106), and a diffusion annealing step (step S107) and removal of the protective layer 314 (step S108) may be performed. This completes the formation flow of the p-type GaN region by plasma doping.

An embodiment of the present invention has been described in detail with reference to the drawings, however, this is a mere exemplary indication and thus does not limit the scope of the claims. The art described in the claims includes modifications and variations of the specific examples presented above. Technical features described in the description and the drawings may technically be useful alone or in various combinations, and are not limited to the combinations as originally claimed. Further, the art described in the description and the drawings may concurrently achieve a plurality of aims, and technical significance thereof resides in achieving any one of such aims.

### (Variants)

The step of decreasing the thickness of the intermediate layer (steps S4 and S16) can be omitted.

Magnesium nitride (MgNx) that constitutes the intermediate layers 13 and 113 may contain other elements, such as fluorine and oxygen.

Device structures to which the art disclosed herein can be applied are not particularly limited to the horizontal MOSFET shown in the second embodiment. It can be applied to various device structures. For example, it may be applied to vertical MOSFETs with trench gates, super junction MOSFETs, PN diodes, heterojunction bipolar transistors (HBTs), HEMTs, etc.

The heating method used in the annealing step (steps S3 and S15) may be a variety of methods. For example, lamp heating, heater heating, high frequency heating, etc. may be used. The atmosphere of the annealing step is not particularly limited to a pure nitrogen atmosphere, but may be a mixture of, for example, H₂, NH₃, Ar, Xe, He, Ne, etc.

Nitride semiconductors to which the art herein can be applied are not particularly limited to GaN. For example, it can be applied to binary nitride semiconductors such as InN and AlN, ternary nitride semiconductors such as AlGaN, GaInN and AlInN, and quaternary nitride semiconductors such as AlGaInN. It is also applicable to sapphire, Si, SiC, SiO2, MgO, Ga2O₃, ZrB₂, spinel, diamond, PET, etc. where at least one AlGaInN-based nitride semiconductor layer is formed.

Application of the Mg diffusion techniques herein is not particularly limited to the upper surface of the substrate 301, but can be applied to the surfaces of various structures. For example, it can be applied to the surfaces of the inner walls of trenches.

The ions implanted in step S102 are not particularly limited to nitrogen ions alone, but may include a variety of ions. For example, it may contain hydrogen ions and fluorine ions.

Step S102 is not particularly limited to ion implantation, since the purpose of this process is to introduce crystal defects. For example, crystal defects may be introduced by electron beam irradiation.

The Mg-containing layer 313 formed in step S103 may be a Mg-containing compound. For example, it may be MgO, MgZnO, etc.

The diffusion annealing step may be performed without forming the protective layer 314. In this case, step S106 can be skipped. The MgO layer 313b may not be removed. In this case, step S105 may be skipped.

In the above embodiments, magnesium (Mg) was used as an example of a group II element to form the p-type region, however, it is not particularly limited to this configuration. The group II elements may be beryllium (Be), calcium (Ca), etc. for example. Silicon (Si) was used as an example of an element to form the n-type region, however, it is not particularly limited to this configuration, and germanium (Ge) and the like may also be used.

The process in step S102 is an example of a defect formation step. The diffusion annealing step of step S107 is an example of a first thermal treatment process. The pre-annealing step of step S104 is an example of a second thermal treatment process. The MgO layer 313b is an example of an altered layer.

1. A method of manufacturing a nitride semiconductor device, the method comprising:
a magnesium layer formation step of forming a magnesium layer that comprises magnesium as a major component on a surface of a nitride semiconductor substrate; and
an annealing step of annealing the nitride semiconductor substrate on which the magnesium layer is formed.

2. The method of manufacturing a nitride semiconductor device according to claim 1, wherein
in the magnesium layer formation step, the magnesium layer is formed on at least a part of a surface of a p-type region of the nitride semiconductor substrate having the p-type region exposed on at least a part of its surface,
in the annealing step, the nitride semiconductor substrate on which the magnesium layer is formed is annealed in an atmosphere containing nitrogen to transform the magnesium layer into an intermediate layer containing magnesium and nitrogen, and
the method further comprises an electrode formation step of forming an electrode layer on at least a part of an upper surface of the intermediate layer.

3. The method of manufacturing a nitride semiconductor device according to claim 2, further comprising:
a step of decreasing a film thickness of the intermediate layer that is performed after the annealing step,
wherein the electrode formation step forms the electrode layer on the upper surface of the intermediate layer after having decreased the film thickness.

4. The method of manufacturing a nitride semiconductor device according to claim 2, wherein an impurity concentration of the p-type region is in a range of 1×10¹⁶ to 1×10²⁰ cm⁻³.

5. The method of manufacturing a nitride semiconductor device according to claim 2, wherein in the magnesium layer formation step, the magnesium layer is selectively formed in a specific region that is at least a part of the surface of the p-type region.

6. The method of manufacturing a nitride semiconductor device according to claim 5, wherein
the magnesium layer formation step comprises:
a step of forming, a mask layer including an opening corresponding to the specific region, on a surface of the nitride semiconductor substrate; and
a step of depositing the magnesium layer via the mask layer.

7. The method of manufacturing a nitride semiconductor device according to claim 5, wherein
an n-type region is exposed on a part of a surface of the nitride semiconductor substrate,
in the magnesium layer formation step, the magnesium layer is formed on at least a part of the surface of the p-type region but is not formed on a surface of the n-type region, and
in the electrode layer formation step, the electrode layer is formed to traverse across the intermediate layer that is formed in the p-type region and the n-type region.

8. The method of manufacturing a nitride semiconductor device according to claim 2, wherein the nitride semiconductor substrate is gallium nitride.

9. The method of manufacturing a nitride semiconductor device according to claim 1, further comprising:
a defect formation step of forming crystal defects in the nitride semiconductor substrate from a surface of nitride semiconductor substrate,
wherein the magnesium layer is a solid layer.

10. The method of manufacturing a nitride semiconductor device according to claim 9, further comprising:
a protective layer formation step of forming a protective layer on a surface of the magnesium layer,
wherein in the annealing step, the nitride semiconductor substrate on which the protective layer is formed is heated.

11. The method of manufacturing a nitride semiconductor device according to claim 10, further comprising:
a pre-annealing step of heating the nitride semiconductor substrate at a lower temperature than in the annealing step,
wherein the pre-annealing step is performed after the magnesium layer formation step and before the protective layer formation step.

12. The method of manufacturing a nitride semiconductor device according to claim 11, further comprising:
a step of removing an altered layer formed on the surface of the magnesium layer by the pre-annealing step,
wherein the protective layer is formed on the surface of the magnesium layer from which the altered layer has been removed.

13. The method of manufacturing a nitride semiconductor device according to claim 1, further comprising:
a defect formation step of forming crystal defects in the nitride semiconductor substrate from a surface of nitride semiconductor substrate,
wherein the magnesium layer is a melt containing magnesium.

14. The method of manufacturing a nitride semiconductor device according to claim 13, wherein
the melt contains Zn, and
a temperature of the melt is 450° C. or higher.

15. The method of manufacturing a nitride semiconductor device according to claim 9, wherein the defect formation step comprises a step of implanting nitrogen ions from a surface of the nitride semiconductor substrate.

16. A nitride semiconductor device comprising:
a nitride semiconductor substrate having a p-type region exposed on at least a part of its surface;
an intermediate layer arranged at least in a part of an upper surface of the p-type region and containing magnesium and nitrogen; and
an electrode layer arranged on at least a part of an upper surface of the intermediate layer.

17. The nitride semiconductor device according to claim 16, wherein the intermediate layer has an amorphous structure.

18. The nitride semiconductor device according to claim 16, wherein
the intermediate layer contains gallium, and
a concentration of the gallium in the intermediate layer decreases as a distance from an interface between the p-type region and the intermediate layer increases.

19. The nitride semiconductor device according to claim 16, wherein an impurity concentration of the p-type region is in a range of 1×10¹⁶ to 1×10²⁰ cm⁻³.

20. The nitride semiconductor device according to claim 16, wherein a thickness of the intermediate layer is 1000 nm or less.

21. The nitride semiconductor device according to claim 16, further comprising:
an n-type region exposed on a part of a surface of the nitride semiconductor substrate,
wherein the electrode layer is formed to traverse across the n-type region and the p-type region, and
the intermediate layer is arranged between the p-type region and the electrode layer but is not arranged between the n-type region and the electrode layer.

22. The nitride semiconductor device according to claim 16, wherein
the nitride semiconductor substrate is gallium nitride, and
the intermediate layer is magnesium nitride.

23. A nitride semiconductor substrate, wherein
a magnesium concentration distribution in a direction perpendicular to a surface of the nitride semiconductor substrate has a maximum value within a first region from the surface to a depth of 100 nanometers, and
the maximum value is 1×10²⁰ cm⁻³ or more.

24. The nitride semiconductor substrate according to claim 23, wherein the magnesium concentration distribution varies in concentration by one or more orders of magnitude within a second region extending in a depth direction from the maximum value and having a width of 100 nanometers or less.

25. The nitride semiconductor substrate according to claim 24, wherein
the magnesium concentration distribution has a singularity point, at which a concentration gradient becomes sharply smaller, in the second region,
a constant concentration region is present, in which a magnesium concentration is substantially constant in the depth direction from the singularity point, and
a width of the constant concentration region in the depth direction is 50 nanometers or more.

26. The nitride semiconductor substrate according to claim 23, wherein a planar density of loop defects in a cross-sectional view of a region where magnesium is added is 1×10⁵ [pcs/cm²] or less.
